(19) United States
(12) Patent Application Publication
(10) Pub. No.: US 2007/0131994 A1
(43) Pub. Date: Jun. 14, 2007

(54) FERROELECTRIC MEMORY AND METHOD FOR MANUFACTURING FERROELECTRIC MEMORY

(75) Inventor: Tatsuo SAWASAKI, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/608,305

(22) Filed: Dec. 8, 2006

(30) Foreign Application Priority Data
Dec. 12, 2005 (JP) 2005-357484

(51) Int. Cl. H01L 29/94

(52) U.S. Cl. 257/295

(57) ABSTRACT

A ferroelectric memory includes a ferroelectric capacitor formed from a lower electrode, an upper electrode and a ferroelectric layer interposed between the lower electrode and the upper electrode; and a metal wiring provided in an interlayer dielectric film, wherein a portion of the metal wiring that may otherwise come in contact with the interlayer dielectric film is covered by a diffusion prevention film.

The entire disclosure of Japanese Patent Application No. 2005-357484, filed Dec. 12, 2005 is expressly incorporated by reference herein.

### BACKGROUND

1. Technical Field

The present invention relates to ferroelectric memories and methods for manufacturing ferroelectric memories.

2. Related Art

A ferroelectric memory, for example, a so-called 1T1C type ferroelectric memory is equipped with a ferroelectric capacitor and a driving transistor for operating the ferroelectric capacitor. It is noted that it is generally important to prevent deterioration of ferroelectric layers during the process of manufacturing ferroelectric capacitors. More specifically, in the process of manufacturing a ferroelectric capacitor, a ferroelectric layer, after having been formed, may be exposed to a hydrogen atmosphere (a reducing atmosphere) in the steps of forming interlayer dielectric films, dry etching and the like. When a ferroelectric layer is exposed to a reducing atmosphere, such as, for example, hydrogen (H₂), water (H₂O) and the like, oxygen composing the ferroelectric layer is reduced, as the ferroelectric layer is generally composed of metal oxides, and the electrical characteristics of the ferroelectric capacitor may be considerably deteriorated.

As a preventive measure to prevent hydrogen damages, a ferroelectric capacitor may be covered at its circumferential area by a hydrogen barrier film (SiN, Al₂O₃ or the like). For example, a hydrogen barrier film may be provided on a first interlayer dielectric film that covers the ferroelectric capacitor and a second interlayer dielectric film is further provided on the hydrogen barrier film (see, for example, Japanese laid-open patent application JP-A-2003-68987). Also, a contact plug that conductively connects to the ferroelectric capacitor is embedded in the second interlayer dielectric film that covers the hydrogen barrier film, and a metal wiring that connects to the contact plug is provided on the second interlayer dielectric film.

As the metal wiring, for example, Al wirings may be generally used, and for example, silicon oxide (SiO₂) is used as the second interlayer dielectric film. When the Al wirings and the silicon oxide are in contact with each other, moisture content that remains (is present) in the silicon oxide and Al may react, whereby Al is oxidized, and hydrogen (H₂) may be generated. Accordingly, in the structure described in the aforementioned patent document, as the metal wiring is provided on the second interlayer dielectric film, moisture content remaining in the second interlayer dielectric film may come in contact with the metal wiring, whereby hydrogen may be generated, and the ferroelectric layer may be deteriorated.

### SUMMARY

In accordance with an advantage of some aspects of the present invention, it is possible to provide ferroelectric memories and methods for manufacturing the ferroelectric memories in which deterioration of ferroelectric capacitors can be prevented by preventing generation of hydrogen that may be caused by contact between a metal wiring and an interlayer dielectric film.

A ferroelectric memory in accordance with an embodiment of the invention includes a ferroelectric capacitor formed from a lower electrode, an upper electrode and a ferroelectric layer interposed between the pair of electrodes, and a metal wiring provided in an interlayer dielectric film, wherein a portion of the metal wiring that may otherwise come in contact with the interlayer dielectric film is covered by a diffusion prevention film.

According to the ferroelectric memory in accordance with the embodiment of the invention, the ferroelectric memory is equipped with the metal wiring in which a portion thereof that may otherwise come in contact with the interlayer dielectric film is covered by the diffusion prevention film. Therefore, for example, the metal wiring composed of aluminum (Al) is prevented from directly contacting the interlayer dielectric film composed of SiO₂, such that generation of hydrogen caused by a chemical reaction between residual moisture content remaining (present) in the interlayer dielectric film and the metal wiring can be prevented.

Accordingly, generation of hydrogen which may occur by contact between the metal wiring and the interlayer dielectric film can be prevented, such that damages caused by hydrogen on the ferroelectric layers composing the ferroelectric capacitor can be alleviated, and the ferroelectric memory that is reliable with less deterioration can be provided.

Also, in the ferroelectric memory in accordance with an aspect of the embodiment, the diffusion prevention film may also be equipped with a function as a hydrogen barrier film having hydrogen barrier property.

Accordingly, when the diffusion prevention film that covers the metal wiring is also provided on the interlayer dielectric film that covers the ferroelectric capacitor, hydrogen can be prevented from penetrating the ferroelectric capacitor, and the ferroelectric capacitor can be better prevented from being deteriorated by hydrogen.

The interlayer dielectric film may preferably be composed of laminated upper and lower interlayer dielectric films, the metal wiring may be provided in the two interlayer dielectric films, the ferroelectric capacitor may be provided in the lower interlayer dielectric film, and the diffusion prevention film may preferably be provided between the interlayer dielectric films.

Because the diffusion prevention film that functions as a hydrogen barrier film is provided between the interlayer dielectric film in which the ferroelectric capacitor is provided and the other interlayer dielectric film laminated on the foregoing interlayer dielectric film, the ferroelectric capacitor can be prevented from damages by hydrogen, and deterioration of the ferroelectric capacitor can be prevented.

Also, in the ferroelectric memory described above, the metal wiring may preferably be electrically connected to the upper electrode of the ferroelectric capacitor.

If hydrogen is generated due to contact between the metal wiring that is connected to the upper electrode of the ferroelectric capacitor and the interlayer dielectric film, the ferroelectric capacitor would more likely be damaged by the hydrogen, as the generation source of hydrogen is close to the ferroelectric capacitor. In accordance with the embodiment of the invention, the metal wiring at the ferroelectric capacitor is covered by the diffusion prevention film, such that the ferroelectric capacitor can be better prevented from damages that may be caused by hydrogen generated by, in particular, the metal wiring and the interlayer dielectric film.

A method for manufacturing a ferroelectric memory in accordance with an embodiment of the invention pertains to a method for manufacturing a ferroelectric memory equipped with a ferroelectric capacitor formed from a lower electrode, an upper electrode and a ferroelectric layer interposed between these electrodes, and a metal wiring provided in an interlayer dielectric film. The method includes the steps of; covering the ferroelectric capacitor with a first dielectric film; forming a contact hole in the first dielectric film which exposes the upper electrode of the ferroelectric capacitor; forming in the contact hole a conductive section that electrically connects to the upper electrode; providing on the first dielectric film a first diffusion prevention film that exposes the conductive section; providing on the first diffusion prevention film a conductive layer that becomes the metal wiring so as to be laminated on the conductive section; forming the metal wiring by etching the conductive layer; providing a second diffusion prevention film that covers upper surface and side surface of the metal wiring; and providing a second dielectric film that covers the metal wiring after providing the second diffusion prevention film.

According to the method for manufacturing a ferroelectric memory in accordance with the embodiment of the invention, the conductive layer provided on the first diffusion prevention film is etched, such that the metal wiring that is covered by the first diffusion prevention film, except a portion thereof on the conductive section, is formed. Also, the metal wiring is covered by the second dielectric film, after the upper surface and the side surface of the metal wiring are covered by the second diffusion prevention film. As a result, it is possible to manufacture a ferroelectric memory equipped with a metal wiring that is covered by a diffusion prevention film (the first and second diffusion prevention films) in a portion thereof that may otherwise come in contact with an interlayer dielectric film (the first and second dielectric films), as described above.

Accordingly, the ferroelectric memory becomes highly reliable with less deterioration, because its structure prevents generation of hydrogen which may be caused by contact between the metal wiring and the interlayer dielectric film, and alleviates damages by hydrogen on the ferroelectric layer composing the ferroelectric capacitor.

### BRIEF DESCRIPTION OF THE DRAWINGS

FIG. 1 is a schematic side cross-sectional view of the structure of a ferroelectric memory.

FIGS. 2A-2E are views for describing the steps of a manufacturing method for manufacturing a ferroelectric memory.

FIGS. 3A-3C are views for describing the steps of the manufacturing method succeeding the steps shown in FIGS. 2A-2E.

FIG. 4 is a view for describing the step of the manufacturing method succeeding the steps shown in FIGS. 3A-3C.

FIG. 5 is a view for describing the step of the manufacturing method succeeding the step shown in FIG. 4.

### DESCRIPTION OF EXEMPLARY EMBODIMENTS

A ferroelectric memory and a method for manufacturing a ferroelectric memory in accordance with embodiments of the invention are described below. First, a ferroelectric memory in accordance with an embodiment of the invention is described.

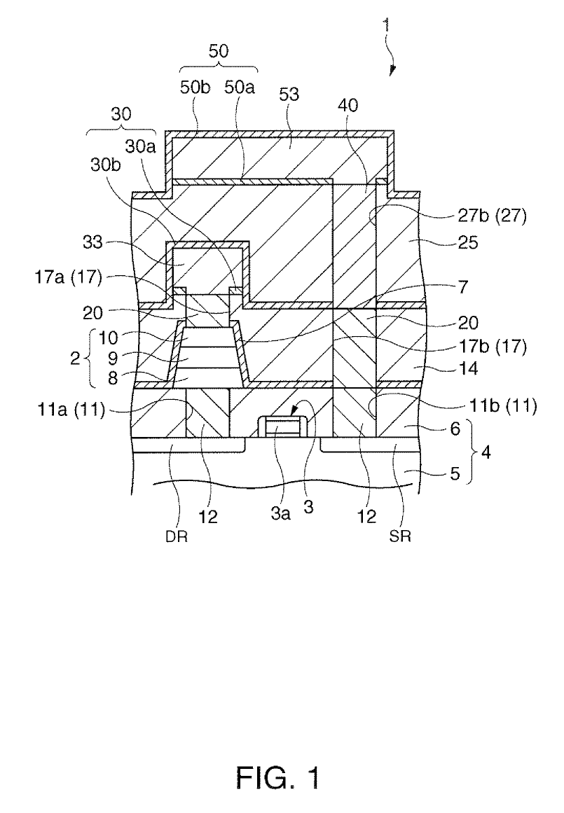

FIG. 1 is a schematic side cross-sectional view of the structure of a ferroelectric memory in accordance with an embodiment of the invention. Reference numeral 1 denotes the ferroelectric memory. The ferroelectric memory 1 has a structure to store charge in an accumulation capacitor as data, like a DRAM cell, and includes a ferroelectric capacitor 2, and a driving transistor (driving element section) 3 for operating the ferroelectric capacitor 2, wherein the driving transistor 3 is formed on a base substrate 4. As shown in FIG. 1, the ferroelectric capacitor 2 includes a pair of an upper electrode 10 and a lower electrode 8, and a ferroelectric layer 9 interposed between the electrodes.

The base substrate 4 is formed with a silicon substrate a, and the driving transistor 3 is formed on a surface section of the silicon substrate 5. As the driving transistor 3, a known structure may be applied, and for example, a thin film transistor (TFT), or a MOSFET may be used. In the illustrated embodiment, a MOSFET is used. A source region SR, a drain region DR and a channel region (not shown) are formed in the silicon substrate 5, and a gate electrode 3a is formed above the channel region through a gate dielectric film.

The driving transistor 3 has the structure described above, and is formed in the base substrate 4. It is noted that the ferroelectric memory 1 in accordance with the embodiment is a so-called 1T1C cell type in which its memory cell has one transistor and one ferroelectric capacitor. The driving transistors 3 corresponding to the ferroelectric capacitors 2 of the respective memory cells are isolated from one another by LOCOS or trench isolation (not shown) formed in the silicon substrate 5.

Further, a first interlayer dielectric film 6 that covers the driving transistor 3 is formed in the base substrate 4 on the silicon substrate 5. The first interlayer dielectric film 6 is composed of silicon oxide (SiO₂), and may be planarized, depending on the requirements, by a CMP (chemical mechanical polishing) treatment, or the like.

Further, the ferroelectric capacitor 2 is formed on the base substrate 4 that has the first interlayer dielectric film 6 formed therein The ferroelectric capacitor 2 is of a stacked type having the lower electrode 8 formed on the first interlayer dielectric film 6, the ferroelectric layer 9 formed on the lower electrode 8, and the upper electrode 10 formed on the ferroelectric layer 9. The lower electrode 8 and the upper electrode 10 may be formed with platinum (Pt), iridium (Ir), iridium oxide (IrO₂) or the like, and the ferroelectric layer 9 is formed with Pb(Zr, Ti) O₃ (PZT), (Pb, La)(Zr, Ti) O₃ (PLZT), or one of the foregoing materials with metal such as niobium (Nb) or the like being added.

It is noted that a contact hole that penetrates the first interlayer dielectric film 6 is formed at the bottom section of the lower electrode 8. More concretely, a plurality of first contact holes 11 are formed in the first interlayer dielectric film 6, and first plugs (first conductive section) 12 composed of tungsten (W) or the like are embedded in the first contact holes 11. The first contact holes 11 may be formed from a contact hole for capacitor 11a that connects to the drain region DR of the driving transistor 3, and a contact hole for base 11b that connects to the source region SR of the driving transistor 3.

With the structure described above, the lower electrode 8 is connected to a first plug 12 formed in the contact hole for capacitor 11a. Further, the first plug 12 is connected to the drain region DR of the driving transistor 3, whereby the ferroelectric capacitor 2 can be operated by the driving transistor 3.

It is noted that the ferroelectric capacitor 2 is covered by a hydrogen barrier film 7 provided at its upper surface (i.e., the upper electrode 10) and its side surface. Also, the hydrogen barrier film 7 covers portions of the surface of the first interlayer dielectric film 6 which are exposed without being covered by the ferroelectric capacitor 2.

The hydrogen barrier film 7 is composed of oxides having a hydrogen barrier property, and may be composed of an insulating hydrogen barrier material. Concretely, as the hydrogen barrier material, oxides of aluminum (Al), oxides of titanium (Ti) or the like may be used. In the present embodiment, aluminum oxide (AlOₓ) is used.

The hydrogen barrier film 7 is formed to a thickness between about 20 nm and about 100 nm. If the thickness is less than 20 nm, the hydrogen barrier effect of the hydrogen barrier film 7 may not be sufliciently obtained, and if the thickness exceeds 100 nm, the load in etching to form contact holes to be described below would become large.

A second interlayer dielectric film 14 that covers the ferroelectric capacitor 2 is provided on the first interlayer dielectric film 6. As the material composing the second interlayer dielectric film 14, silicon oxide (SiO₂) may be used, like the first interlayer dielectric film 6. It is noted that, as described above, the ferroelectric capacitor 2 is covered by the hydrogen barrier film 7. Therefore, even if hydrogen is generated, for examples when the second interlayer dielectric film 14 is formed, deterioration of the ferroelectric layer 9 by hydrogen can be prevented.

Also, a plurality of second contact holes 17 are formed in the second interlayer dielectric film 4, and second plugs (second conductive sections) 20 composed of tungsten (W) or the like are embedded in the second contact holes 17. The second contact holes 17 may be formed from a second contact hole for capacitor 17a that connects to the upper electrode 10 of the ferroelectric capacitor 2, and a second contact hole for base 17b that connects to the contact hole for base 11b that connects to the source region SR of the driving transistor 3.

As the second contact hole for base 17b is formed connected with the contact hole for base 11b, the plug 20 is conductively connected to the first plug 12 provided in the contact hole for base 11b. Also, the second contact hole for capacitor 17a is formed in a state penetrating the hydrogen barrier film 7, such that the hydrogen barrier film 7 covers the ferroelectric capacitor 2 except a connecting section between the upper electrode 10 and the second plug 20.

A metal wiring 33 is formed on the second interlayer dielectric film 14. The metal wiring 33 is connected to the upper electrode 10 through the second plug 20 connecting to the upper electrode 10. The upper electrode 10 is energized through the metal wiring 33. The metal wiring may be composed of a film of successively laminated titanium nitride (TiN), aluminum alloy, and titanium nitride (TiN) layers (hereafter, the film of “ctitanium nitride (TiN), aluminum alloy, and titanium nitride (TiN) layers” may be referred to as a conductive layer). Further, a third interlayer dielectric film 25 that covers the metal wiring 33 is formed on the second interlayer dielectric film 14.

It is noted that, if the metal wiring 33 composed of a conductive layer to be described in greater detail comes in contact with the interlayer dielectric films 14 and 25 composed of SlO₂, moisture content present in the interlayer dielectric films 14 and 25 would diffuse in the metal wiring 33, and come in contact with aluminum (Al) alloy contained in the metal wiring 33, which causes a chemical reaction (2Al+3H₂O→Al₂O₃+3H₂), whereby hydrogen (H₂) is generated as a consequence. As a result, the ferroelectric layer 9 of the ferroelectric capacitor 2 may be deteriorated by the hydrogen, and the electrical characteristics of the ferroelectric capacitor 2 may be deteriorated.

Accordingly, in the present embodiment, the metal wiring 33 is covered by a diffusion prevention film 30 in areas that may otherwise come in contact with the interlayer dielectric films 14 and 25. It is noted that the diffusion prevention film 30 is a film that prevents moisture content present in the interlayer dielectric films from diffusing into the metal wiring 33. The diffusion prevention film 30 is composed of a film that is denser than silicon oxide (SiO₂) composing the interlayer dielectric films, such that the diffusion prevention film 30 can prevent diffusion of moisture content present in the interlayer dielectric films (silicon oxide). In accordance with the present embodiment, the diffusion prevention film 30 is composed of a first diffusion prevention film 30a and a second diffusion prevention film 30b.

The first diffusion prevention film 30a and the second diffusion prevention film 30b may be formed with the same material, and may be composed of oxides of aluminum (Al), oxides of titanium (Ti) or the like. In the present embodiment, the diffusion prevention film 30 is composed of aluminum oxide (AlOₓ), like the first hydrogen barrier film 7. In other words, because the diffusion prevention film 30 is composed of the same material as that of the hydrogen barrier film 7, the diffusion prevention film 30 has the capability to prevent moisture content diffusion described above and hydrogen barrier capability. The first diffusion prevention film 30a and the second diffusion prevention film 30b each have a film thickness between 20 nm and 100 nm. If the film thickness is less than 20 nm, the hydrogen barrier effect may not be sufficiently achieved, and if the film thickness exceeds 100 nm, the load in etching to form contact holes to be described below would become large.

Concretely, the first diffusion prevention film 30a is formed on a lower surface side of the metal wiring 33. It is noted that, as described above, the second plug 20 is connected to the lower surface side of the metal wiring 33. Therefore, the lower surface side of the metal wiring 33 is covered by the first diffusion prevention film 30a except a portion connecting to the second plug 20.

Also, the second diffusion prevention film 30b is formed on the upper surface and side surface of the metal wiring 33. This structure creates a state in which the second diffusion prevention film 30b is present between the upper surface and side surface of the metal wiring 33 and the third interlayer dielectric film. By this structure, the metal wiring 33 is covered by the diffusion prevention film 30 on its lower surface, upper surface and side surface except a portion thereof connecting to the second plug 20. Therefore, the aluminum would not come in contact with moisture content (H₂O) in the interlayer dielectric film, and generation of hydrogen is therefore prevented, such that the problem of deterioration of the electrical characteristics of the ferroelectric capacitor 2 can be prevented.

Further, a third contact hole 27 that connects to the second contact hole for base 17b is formed in the third interlayer dielectric film 25. Also, a third plug 40 composed of tungsten (W) or the like is embedded in the third contact hole 27. It is noted that the third contact hole 27a is provided in a state penetrating the second diffusion prevention film 30b. By this, the third plug 40 and the second plug 20 can have good mutual connection. Accordingly, a second metal wiring 53 that conductively connects to the source region SR through the first through third plugs is provided on the surface of the third interlayer dielectric film 25.

It is noted that the diffusion prevention film (second diffusion prevention film 30b) 30, that is equipped with the function as a hydrogen barrier film described above, is provided between the second interlayer dielectric film 14 and the third interlayer dielectric film 25. In other words, the second diffusion prevention film 30b can prevent the ferroelectric capacitor 30 from being damaged by hydrogen that is generated when the third interlayer dielectric film 25 that covers the metal wiring 33 is formed on the second interlayer dielectric film 14.

Also, the second metal wiring 53 is composed of the same material (a conductive layer composed of titanium nitride (TiN), aluminum alloy, and titanium nitride (TiN)) as that of the metal wiring 33, and is covered by a diffusion prevention film 50 in portions that may otherwise contact the interlayer dielectric film 25. More concretely, the diffusion prevention film 50 is composed of a third diffusion prevention film 50a that covers a bottom surface of the second metal wiring 53 which may otherwise contact the third interlayer dielectric film 25, and a fourth diffusion prevention film 50b that covers upper surface and side surface of the second metal wiring 53. The third and fourth diffusion prevention films 50a and 50b are formed with the same material as that of the first and second diffusion prevention films 30a and 30b, and are equipped with hydrogen barrier capability. It is noted that the surface of the second metal wiring 53 is covered by an interlayer dielectric film composed of SiO₂, though an illustration thereof is omitted. Accordingly, the second metal wiring 53 would not come in contact with the interlayer dielectric film covering its circumferential areas, therefore a chemical reaction between moisture content present in the interlayer dielectric film and aluminum (Al) would not take place, and hydrogen would not be generated, such that deterioration of the ferroelectric layer 9 by hydrogen can be prevented.

The ferroelectric memory 1 in accordance with the embodiment of the invention is equipped with the metal wirings 33 and 53 that are covered by the diffusion prevention films 30 and 50 in portions that may otherwise contact the interlayer dielectric films 14 and 25, respectively. Therefore, as described above, direct contact between aluminum (metal wirings) and SiO₂ (interlayer dielectric films) is prevented, and generation of hydrogen that may be caused by a chemical reaction between moisture content present in the interlayer dielectric films 14 and 25 and aluminum composing the metal wirings can be prevented.

Accordingly, the ferroelectric memory in accordance with the embodiment of the invention is highly reliable with less deterioration in its electrical characteristics because it is equipped with the ferroelectric capacitor 2 in which generation of hydrogen can be prevented, and therefore damages to the ferroelectric layer 9 by hydrogen can be alleviated.

Also, the diffusion prevention film 30 also functions as a hydrogen barrier film equipped with hydrogen barrier capability, whereby the ferroelectric capacitor 2 is prevented from being exposed to a hydrogen atmosphere (hydrogen) that is generated in the process of manufacturing the ferroelectric memory 1, and the ferroelectric memory 1 that has less deterioration in electrical characteristics during the manufacturing process can be provided.

Method for manufacturing Ferroelectric Memory

A method for manufacturing a ferroelectric memory in accordance with an embodiment of the invention is described below based on the method for manufacturing the ferroelectric memory 1 with the structure described above.

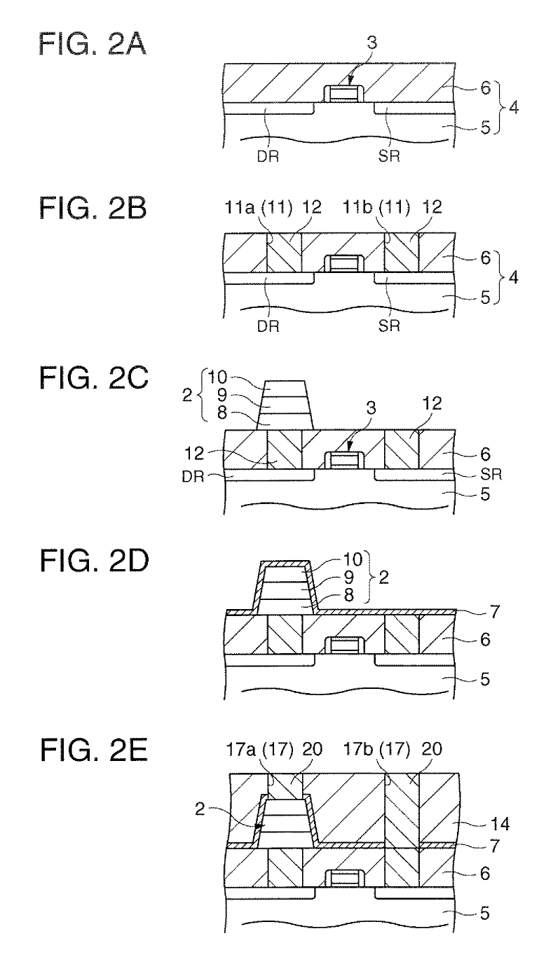

First, as shown in FIG. 2A, a driving transistor 3 is formed on a silicon substrate 5 beforehand by a known method, and then an SiO₂ film that covers the driving transistor 3 is deposited by a CVD method or the like as a first interlayer dielectric film 6. The thickness of the first interlayer dielectric film 6 may be about 1500 nm, such that the transistor 3 would not be exposed when planarization is conducted in the next step.

The first interlayer dielectric film 6 is planarized by a chemical mechanical polishing method or the like. By planarizing the first interlayer dielectric film 6 in this manner, the first interlayer dielectric film 6, in particular, a portion thereof immediately below a ferroelectric capacitor 2 to be described can be made thinner, and therefore a first contact hole 11 that connects to the ferroelectric capacitor 2 can be readily formed. Also, as the planarization treatment is conducted by a chemical mechanical polishing method, the processing becomes relatively easy, and the treatment can be stabilized.

Prior to forming the ferroelectric capacitor 2, and after the first interlayer dielectric film 6 has been formed, the first interlayer dielectric film 6 is etched to form first contact holes 11, as shown in FIG. 2B. More concretely, a resist pattern (not shown) is formed on the first interlayer dielectric film 6 by a known method. By using the resist pattern as a mask, the first interlayer dielectric film 6 is etched by a reactive ion etching (RIE) method, an inductively coupled plasma (ICP) etching method, or an electron cyclotron resonance (ECR) plasma etching method, thereby forming a contact hole for capacitor 1a that connects to a drain region DR of the driving transistor 3, and a contact hole for base 11b that connects to a source region SR of the driving transistor 3.

Then, a conductive material is embedded in the first contact holes 11. The conductive material may be formed in a film and embedded in the following manner. First, titanium (Ti) and titanium nitride (TiN) are formed as an adhesion layer by a sputter method or the like, and then a film of tungsten (W) is formed. In this manner, the conductive material is embedded in the first contact holes 11, thereby forming first plugs 12. Accordingly, as shown in FIG. 2B, a base substrate 4 in which the first plugs 12 are provided on the source region SR and the drain region DR of the driving transistor 3 is formed.

Then, a ferroelectric capacitor 2 is formed on the first interlayer dielectric film 6 in a manner that the ferroelectric capacitor 2 is stacked on the first plug 12. More specifically, for example, by conducting a spin coat method or a dipping method using sol-gel materials or MOD materials, a sputter method, a MOCVD method, a laser aberration method and the like, composing materials for a lower electrode 8, a ferroelectric layer 9 and an upper electrode 10 are successively laminated, a resist pattern is formed on the laminated body, and the laminated body is etched, using the resist pattern as a mask, by a reactive ion etching (RIE) method or an inductively coupled plasma (ICP) etching method, whereby the ferroelectric capacitor 2 shown in FIG. 2C is formed.

Then, as shown in FIG. 2D, a hydrogen barrier film 7 is provided on the first interlayer dielectric film 6, in a manner to cover top surface and side surface of the ferroelectric capacitor 2. More concretely, the hydrogen barrier film 7 composed of AlOₓ or the like is formed by a sputtering method, or a CVD method. The thickness of the hydrogen barrier film 7 composed of AlOₓ is formed to be between about 20 nm and 100 nm. In this instance, portions of the surface of the first interlayer dielectric film 6 that are exposed without being covered by the ferroelectric capacitor 2 is covered by the hydrogen barrier film 7.

After providing the hydrogen barrier film 7, a second interlayer dielectric film 14 that covers the ferroelectric capacitor 2 is formed. More specifically, SiO₂ is deposited in a film, and then the film is planarized by a CMP (chemical mechanical polishing) method, thereby forming the interlayer dielectric film 14. As a result, the hydrogen barrier film 7 is placed between the first interlayer dielectric film 6 and the second interlayer dielectric film 14.

Then, a resist pattern (not shown) is formed on the second interlayer dielectric film 14 by a known method. Then, by using the resist pattern as a mask, a reactive ion etching (RIE) method, an inductively coupled plasma (ICP) etching method, or an electron cyclotron resonance (ECR) plasma etching method is conducted to etch the second interlayer dielectric film 14 and the hydrogen barrier film 7 together, thereby forming contact holes 17 at specified positions.

More specifically, in the step of forming the second contact holes, a second contact hole for capacitor 17a that connects to the upper electrode 10 of the ferroelectric capacitor 2, and a second contact hole for base 17b that connects to the first plug 12 that conductively connects to the source region SR of the driving transistor 3 are formed.

Then, films of titanium (Ti) and titanium nitride (TiN) are formed inside the contact holes 17 as an adhesion layer, and a film of tungsten (W) is formed, thereby forming second plugs 20 shown in FIG. 2E. Accordingly, a two-stage plug composed of the first plug 12 and the second plug 20 connecting to the first plug 12 is formed on the source region SR of the driving transistor 3.

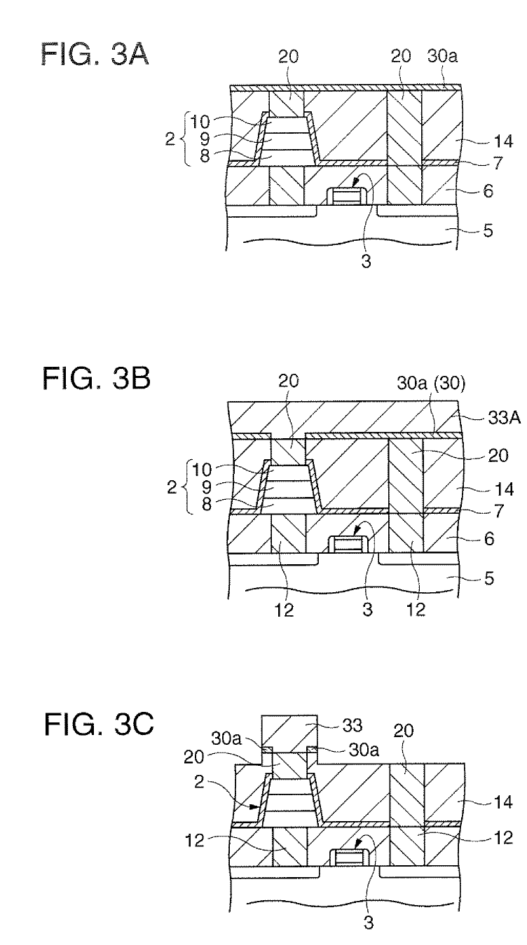

Then, a first diffusion prevention film 30a is provided on the second interlayer dielectric film 14. More concretely, as shown in FIG. 3A, a first diffusion prevention film 30a composed of AlOₓ or the like is formed by a sputter method, or a CVD method. The first diffusion prevention film 30a composed of AlOₓ is formed in a thickness between about 20 nm and 100 nm, as described above. Then, the first diffusion prevention film 30a is etched by a known method, to remove a portion thereof immediately above the second plug 20 that connects to the upper electrode 10 of the ferroelectric capacitor 2.

Next, as shown in FIG. 3B, as a metal wiring 33, layers of titanium nitride (TiN), aluminum alloy, and titanium nitride (TiN) (hereafter, the film of “titanium nitride (TiN), aluminum alloy, and titanium nitride (TiN) layers” may be referred to as a conductive layer 33A) are successively laminated on the first diffusion prevention film 30a such that the layers are deposited over the first plug 12. These layers may be formed by, for example, a sputter method or a MOCVD method. In this instance, the conductive layer 33A is in a state conductively connected to the first plug 12 at a portion where the above-described hydrogen barrier film 7 is removed.

Then, the conductive layer 33A is patterned by etching, thereby forming a metal wiring 33, as shown in FIG. 3C. More concretely, a resist pattern (not shown) is formed on the conductive layer 33A, and then by using the resist pattern as a mask, the conductive layer 33A is etched by a reactive ion etching (RIE) method or an inductively coupled plasma (ICP) etching method, thereby forming the metal wiring 33.

In the present embodiment, the conductive layer 33A is etched until the etching reaches at least the second interlayer dielectric film 14, thereby forming the metal wiring 33. In other words, the conductive layer 33A is over-etched down to the second interlayer dielectric film 14, whereby the metal wiring 33 is formed. In this instance, the metal wiring 33 is covered by the first diffusion prevention film 30a except a portion thereof on the second plug 20. In the present embodiment, the upper surface of the second interlayer dielectric film 14 where the metal wiring 33 is not provided has a step difference caused by the over-etching described above.

At this time, portions of the first diffusion prevention film 30a provided on the second interlayer dielectric film 14 which are not covered by the metal wiring 33 are removed. However, this is not a problem because the second interlayer dielectric film 14 shall be covered again by a second diffusion prevention film 30b in a step to be conducted later. In this manner, by allowing over-etching at the time of etching the metal wiring 33, a greater margin can be given to the etching amount, which results in a highly stable etching step.

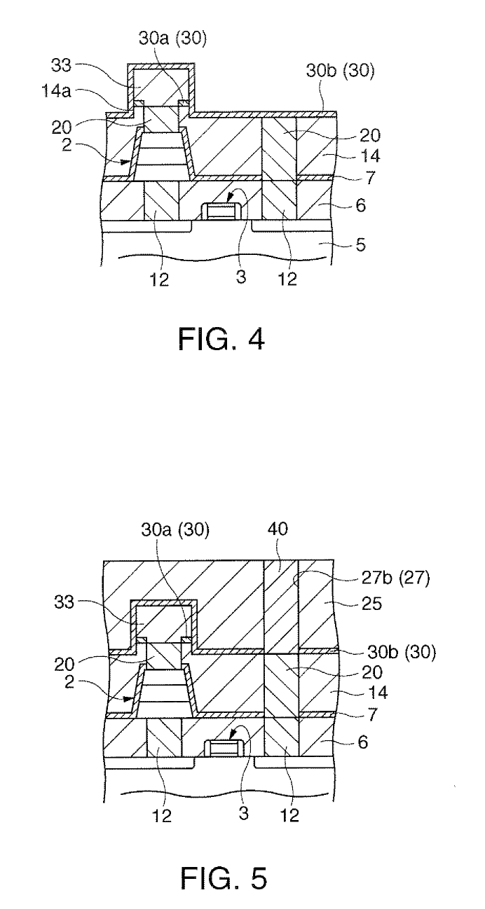

Then, as shown in FIG. 4, a second diffusion prevention film 3Ob is provided on the second interlayer dielectric film 14. More concretely, a film of AlOₓ is formed by a sputtering method or a CVD method, like the first diffusion prevention film 30a, thereby forming the second diffusion prevention film 30b. The second diffusion prevention film 30b is formed to a thickness between about 20 nm and about 100 nm, as described above. By this step, the surfaces of the second interlayer dielectric film 14 exposed without being covered by the metal wiring 30 are covered by the second diffusion prevention film 30b. It is noted that side surface sections 14a continuous with the to surface of the second interlayer dielectric film 14 defined at the step difference formed by over-etching are covered by the second diffusion prevention film 30b, as described above.

After the second diffusion prevention film 3Ob has been provided, a third interlayer dielectric film 25 that covers the metal wiring 33 is formed. More concretely, SiO₂ is deposited by a CVD method or the like, thereby forming the third interlayer dielectric film 25. As a result, the diffusion prevention films (the first diffusion prevention film 30a and the second diffusion prevention film 30b) 30 are provided between the third interlayer dielectric film 25 and the second interlayer dielectric film 14, and between the third interlayer dielectric film 25 and the metal wiring 33.

Then, a resist pattern (not shown) is formed on the third interlayer dielectric film 25 by a known method. Then, by using the resist pattern as a mask, the etching method describe above is conducted to etch the third interlayer dielectric film 25 and the second diffusion prevention film 30b together, thereby forming a third contact hole 27 at a specified position. A conductive material is embedded in the third contact hole 27, thereby forming a third plug 40 that is electrically connected to the second plug 20. Accordingly, an electrical connection to the source region SR of the driving transistor 3 can be made through the first, second and third plugs 12, 20 and 40.

Then, a third diffusion prevention film 50a shown in FIG. 1 is formed with a connection portion of the third plug 40 being exposed, in a manner similar to the process described above in which the diffusion prevention film 30 that covers the metal wiring 33 and the second interlayer dielectric film 14 is formed. Then, a second metal wiring 53 is formed on the third diffusion prevention film 50a, and a fourth diffusion prevention film 50b that covers the second metal wiring 53 is formed. Then, the second metal wiring 53 is covered by an interlayer dielectric film, whereby a device equipped with the ferroelectric memory 1 in accordance with the embodiment of the invention is completed.

According to the manufacturing method applied to the ferroelectric memory 1, the conductive layer 33A for metal wirings provided on the first diffusion prevention film 30a is etched, such that a metal wiring that is covered by the first diffusion prevention film 30a except a portion on the second plug conductive section is formed. Also, after providing the second diffusion prevention film on the top and side surfaces of the metal wiring, the metal wiring is covered by the second interlayer dielectric film. Therefore, it is possible to manufacture a ferroelectric memory that is equipped with metal wirings that are covered by diffusion prevention films (the first and second diffusion prevention films) in portions thereof that may otherwise be in contact with interlayer dielectric films (the first and second dielectric films). Accordingly, the ferroelectric memory is highly reliable with less deterioration, because its structure prevents generation of hydrogen which may be caused by contact between the metal wiring and the interlayer dielectric films, and alleviates damages by hydrogen on the ferroelectric layers composing the ferroelectric capacitor.

The ferroelectric memory 1 may be applicable to various electronic devices, such as, for example, cellular phones, personal computers, liquid crystal devices, electronic notebooks, pagers, POS terminals, IC cards, mini-disc players, liquid crystal projectors, engineering workstations (EWS), word processors, televisions, view finder or monitor-direct viewing type video recorders, electronic desk-top calculators, car-navigation systems, devices equipped with touch-panels, clocks, gaming devices, and electrophoretic devices.

It is noted that the invention is not limited to the embodiments described above, and various changes can be made without departing from the subject matter of the invention. For example, in the embodiment described above, a 1T1C type ferroelectric memory is described. However, the invention is also applicable to 2T2C type ferroelectric memories.

What is claimed is:

1. A ferroelectric memory comprising:
a ferroelectric capacitor formed from a lower electrode, an upper electrode and a ferroelectric layer interposed between the lower electrode and the upper electrode;
a metal wiring provided in an interlayer dielectric film; and
a diffusion prevention film that covers the metal wiring in a portion thereof that may contact the interlayer dielectric film.

2. A ferroelectric memory according to claim 1, wherein the diffusion prevention film is equipped with a function as a hydrogen barrier film having hydrogen barrier property.

3. A ferroelectric memory according to claim 2, wherein the interlayer dielectric film is composed of laminated upper and lower interlayer dielectric films, the metal wiring is provided in the upper and lower interlayer dielectric films, the ferroelectric capacitor is provided in the lower interlayer dielectric film, and the diffusion prevention film is provided between the interlayer dielectric films.

4. A ferroelectric memory according to claim 1, wherein the metal wiring is electrically connected to the upper electrode of the ferroelectric capacitor,

5. A method for manufacturing a ferroelectric memory equipped with a ferroelectric capacitor formed from a lower electrode, an upper electrode and a ferroelectric layer interposed between the lower and upper electrodes, and a metal wiring provided in an interlayer dielectric film, the method comprising the steps of:
covering the ferroelectric capacitor with a first dielectric film;
forming a contact hole in the first dielectric film which exposes the upper electrode of the ferroelectric capacitor;
forming in the contact hole a conductive section that electrically connects to the upper electrode;
providing on the first dielectric film a first diffusion prevention film that exposes the conductive section;
providing on the first diffusion prevention film a conductive layer that becomes the metal wiring so as to be laminated on the conductive section;
forming the metal wiring by etching the conductive layer;
providing a second diffusion prevention film that covers upper surface and side surface of the metal wiring; and
providing a second dielectric film that covers the metal wiring after providing the second diffusion prevention film.
